(19) United States
(12) Patent Application Publication
(10) Pub. No.: US 2023/0205066 A1
(43) Pub. Date: Jun. 29, 2023

(54) COOLING DEVICE, PROJECTION DISPLAY APPARATUS, AND OPTICAL APPARATUS

(71) Applicant: CANON KABUSHIKI KAISHA, Tokyo (JP)

(72) Inventor: KEI TERANISHI, Kanagawa (JP)

(21) Appl. No.: 18/080,039

(22) Filed: Dec. 13, 2022

(30) Foreign Application Priority Data
Dec. 27, 2021 (JP) 2021-212304

(51) Int. Cl. G03B 21/16; H05K 7/20

(52) U.S. Cl. CPC G03B 21/16; H05K 7/20263; H05K 7/20272

(57) ABSTRACT

A cooling device includes: a pressure feeding unit configured to feed a cooling medium for cooling a member; a channel configured to guide the cooling medium to the member, the channel including; a first channel, a second channel, a bent portion that connects the first channel and the second channel; and a heat sink unit disposed in the bent portion in the channel and configured to cool the cooling medium, in which an inflow portion of the first channel from which the cooling medium flows into the heat sink unit includes an outer circumferential side of the bent portion, and in which in a projection onto a projection surface which is a surface perpendicular to a first direction which is a flowing direction of the cooling medium in the first channel, a projection area of the heat sink unit is larger than a projection area of the inflow portion.

### BACKGROUND OF THE INVENTION

### Field of the Invention

The present invention relates to a cooling device, a projection display apparatus, and an optical apparatus.

### Description of the Related Art

In a projection display apparatus such as a projector that includes a plurality of optical components arranged inside, these optical components generate heat due to absorption of light emitted from a light source or self-heating, and temperature of the optical components increases. An increase in the temperature of the optical component causes deterioration of the life of the optical component and deterioration of the quality of a projected image, so that a cooling device for cooling the optical components is necessary. In order to increase a cooling capacity of the cooling device, a method has been proposed in which a heat sink is disposed in a flow path of a cooling medium to decrease the temperature of the cooling medium. For example, Japanese Patent Application Laid-Open No. 2016-224399 discloses a method of cooling an object to be cooled by cooling air as a cooling medium in a flow path of the cooling medium by a heat sink and circulating the cooled air by a cooling fan.

However, in a configuration in which the heat sink is disposed in the flow path of the cooling medium as disclosed in Japanese Patent Application Laid-Open No. 2016-224399, a heat transfer efficiency between air as a cooling medium and the heat sink is low and it is therefore difficult to cool the air in a short time during which the air passes through the heat sink. That is, there is a problem that the air passing through the heat sink is hard to be cooled even if the temperature of the heat sink is low. On the other hand, there is a method of increasing a surface area of the heat sink to cool the air while further increasing the heat transfer efficiency, but a problem arises in that a size of a housing increases.

### SUMMARY OF THE INVENTION

The present invention provides a cooling device for cooling an optical apparatus, which is small in size and has a high cooling capacity.

A cooling device according to an aspect of the present invention includes: a pressure feeding unit configured to feed a cooling medium for cooling a member; a flow channel configured to guide the cooling medium to the member, the flow channel including; a first flow channel, a second flow channel, a bent portion that connects the first flow channel and the second flow channel; and a heat sink unit disposed in the bent portion in the flow channel and configured to cool the cooling medium, in which an inflow portion of the first flow channel from which the cooling medium flows into the heat sink unit includes an outer circumferential side of the bent portion, and in which in a projection onto a projection surface which is a surface perpendicular to a first direction which is a flowing direction of the cooling medium in the first flow channel, a projection area of the heat sink unit is larger than a projection area of the inflow portion.

According to the present invention, it is possible to provide a cooling device for cooling an optical apparatus, which is small in size and has a high cooling capacity.

Further features of the present invention will become apparent from the following description of exemplary embodiments with reference to the attached drawings.

### BRIEF DESCRIPTION OF THE DRAWINGS

FIG. 1 is a schematic diagram of a projection display apparatus according to an embodiment of the present invention.

FIG. 2 is an optical schematic diagram of the projection display apparatus according to an embodiment of the present invention.

FIG. 3 is a schematic diagram of a cooling device in a first embodiment of the present invention.

FIG. 4 is a sectional view taken along a line A-A in FIG. 3 of a bent portion of the first embodiment of the present invention.

FIG. 5 is a detailed view illustrating a configuration relating to heat absorption and heat radiation of a bent portion according to the first embodiment of the present invention.

FIG. 6A is a view visualizing the air flow in the bent portion of the first embodiment of the present invention.

FIG. 6B is a reference diagram for explaining the effect of the throttling portion according to the first embodiment of the present invention.

FIG. 7 is a schematic diagram of a modification of the bent portion of the first embodiment of the present invention.

FIG. 8 is a schematic diagram of a cooling device according to a second embodiment of the present invention.

FIG. 9 is a sectional view taken along a line B-B in FIG. 8 of a bent portion according to the second embodiment of the present invention.

FIG. 10 is a diagram visualizing an air flow in a bent portion according to the second embodiment of the present invention.

FIG. 11 is a schematic diagram of a liquid cooling system according to a third embodiment of the present invention.

FIG. 12 is a schematic diagram of a cooling device according to the third embodiment of the present invention.

FIG. 13 is a schematic diagram of a cooling device according to a fourth embodiment of the present invention.

### DESCRIPTION OF THE EMBODIMENTS

Hereinafter, embodiments of a cooling device according to the present invention will be described.

### Embodiment 1

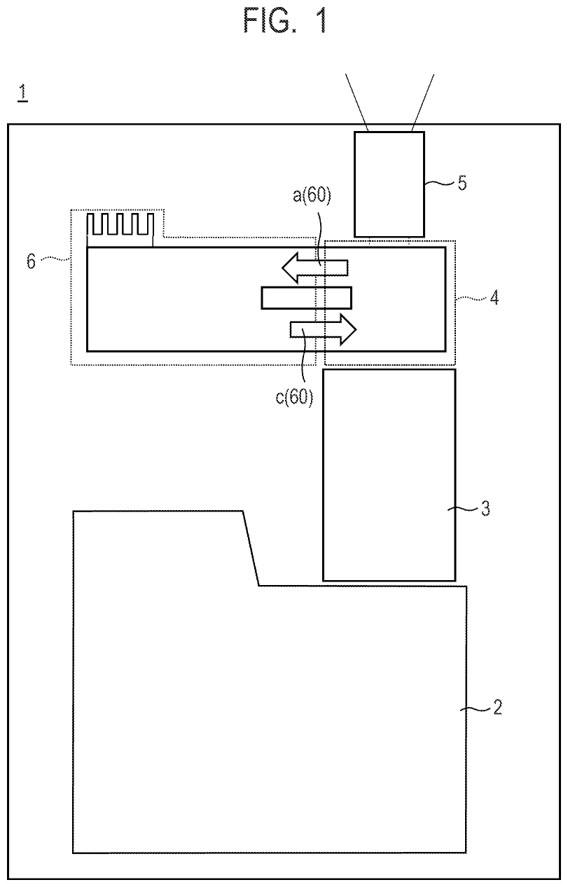

FIG. 1 is a schematic diagram illustrating a configuration of a projection display apparatus 1 including a cooling device according to the first embodiment. The projection display apparatus 1 includes a light source optical system 2, an illumination optical system 3, a color separating and combining optical system (a color separating and combining unit) 4, a projection lens 5, and a cooling device 6 that cools the color separating and combining optical system 4.

The projection display apparatus 1 generates an illumination light by a light source optical system 2 including a plurality of laser diodes and a phosphor, and irradiates an illumination optical system 3 with the illumination light. The illumination optical system 3 includes a plurality of lenses to make the brightness uniform and make the polarization directions uniform, irradiates the color separating and combining optical system 4 with the light. The color separating and combining optical system 4 modulates the irradiated light in accordance with an input signal to generate a projection image, enlarges the projection image by passing through a projection lens 5 at a subsequent stage, and projects the enlarged projection image onto a screen (not shown).

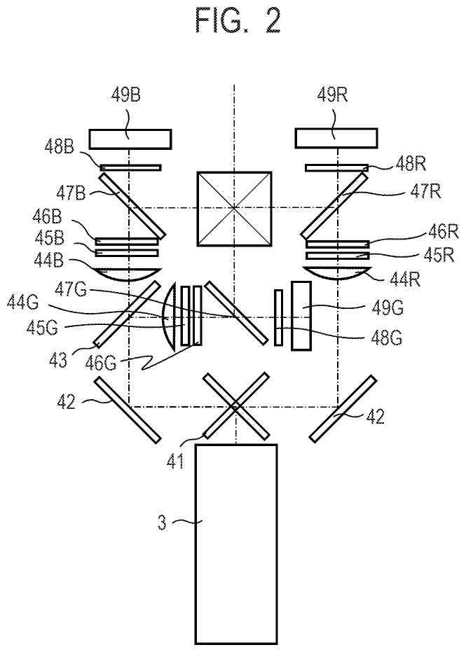

Next, a configuration of the color separating and combining optical system 4 will be described in detail with reference to FIG. 2.

A cross dichroic mirror 41 separates an incident light into a mixed color light of green (G) and blue (B) and a red (R) light. Reference numeral 42 denotes a reflection mirror. A dichroic mirror 43 reflects the G light and transmits the B light. Reference numerals 44R, 44G, and 44B are condenser lenses for the R light, the G light, and the B light, respectively. Reference numerals 45R, 45G, and 45B are half-wavelength (λ/2) plates for the R light, the G light, and the B light, respectively. Reference numerals 46R, 46G, and 46B are reflective polarizing plates for the R light, the G light, and the B light, respectively. Reference numerals 47R, 47G, and 47B are wire grid polarizers (WG polarizers) for the R light, the G light, and the B light, respectively. Reference numerals 48R, 48G, and 48B are retardation compensation plates for the R light, the G light, and the B light, respectively. Reference numerals 49R, 49G, and 49B are reflective liquid crystal panels for the R light, the G light, and the B light, respectively. The light transmitted through the WG polarizer 47 is guided to the reflective liquid crystal panel 49, is reflected by the reflective liquid crystal panel 49, is reflected again by the WG polarizer 47, and is sent to the projection lens 5 after the R, G, and B lights are combined. By arranging these components in a substantially sealed space, adhesion of dust entering the housing of the projection display apparatus 1 from an outside air is suppressed. In this embodiment, the reflective liquid crystal panel 49 in the color separating and combining optical system 4 is an optical member to be cooled by the cooling device 6. Although the reflective liquid crystal panel 49 is used in the present embodiment, a transmission type liquid crystal panel or a DMD (Digital Mirror Device) may be used.

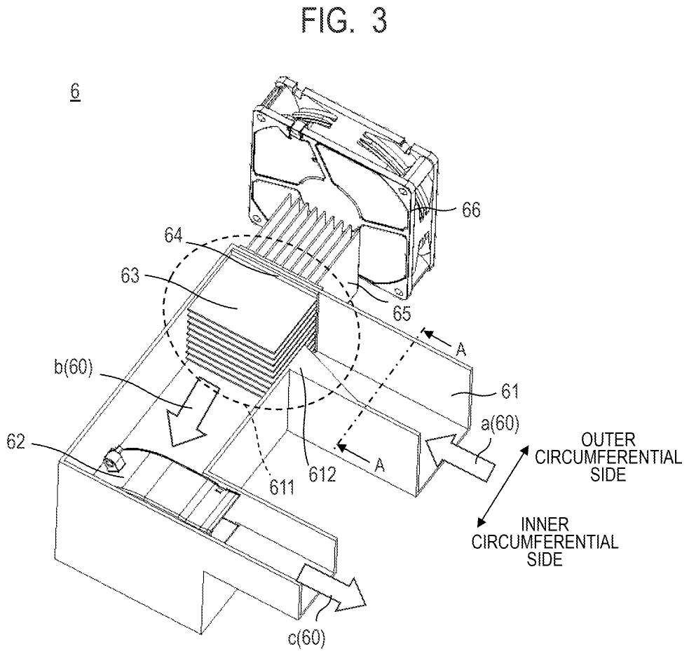

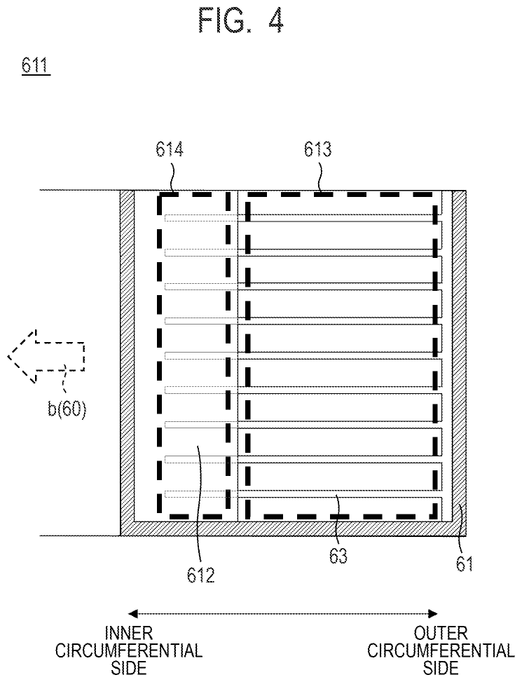

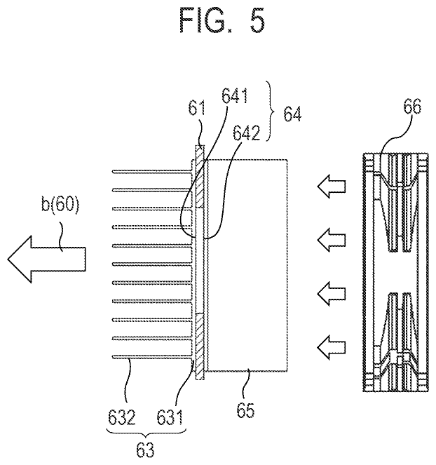

Referring to FIGS. 3, 4, and 5, a configuration of the cooling device 6 according to the first embodiment will be described. FIG. 3 is a configuration diagram of the cooling device 6 according to the first embodiment. FIG. 4 is a cross-sectional view taken along a line A-A in FIG. 3, and illustrates a positional relationship between a cooling duct 61 and the heat sink (heat sink unit) 63 as viewed from a normal direction (a direction indicated by an arrow a in FIGS. 1 and 3, a first direction) with respect to a surface on which an air 60 flows into the bent portion 611. FIG. 5 is a detailed view for describing a configuration relating to a heat absorption and a heat radiation of the bent portion 611 as viewed from the normal direction (direction of the arrow a).

Reference numeral 60 denotes an air as a cooling medium circulating in the sealed space. Reference numeral 61 denotes a cooling duct as a flow path which forms a substantially sealed space together with the color separating and combining optical system 4, and has a throttling portion 612 in the inner circumferential side near the bent portion 611. The bent portion 611 connects a first flow channel that guides the air 60 to the bent portion 611 and a second flow channel that guides the air 60 flowing out from the bent portion 611 with each other. Reference character a denotes a normal direction of a surface on which the air 60 flows into the bent portion 611, reference character b denotes a normal direction (second direction) of a surface which the air 60 flows out from the bent portion 611, and reference character c denotes a blowing direction of the air 60 by a sirocco fan 62. The air 60 flows in the cooling duct 61 along the directions a, b, and c, and is sent to the color separating and combining optical system 4.

As shown in FIG. 4, the bent portion 611 includes an inflow portion 613 through which the air 60 flows into the bent portion 611 from the first flow channel. The heat sink 63 includes an overlap portion 614 having a projection area (projection area on a projection surface perpendicular to the first direction) larger than the inflow portion 613 as viewed from the normal direction (first direction) a and hidden behind the throttling portion 612 as viewed from the normal direction a. That is, the cooling duct 61 as a flow path includes the throttling portion 612 that reduces the cross-sectional area of the cooling duct 61 to make the air 60 to flow into the heat sink 63 from the outer circumferential side of the heat sink 63. In the present embodiment, the overlap portion 614 forms a throttling portion 612.

The sirocco fan 62 as a fluid pressure feeding unit circulates the air 60 in the substantially sealed space. The heat sink 63 includes a base part 631 and a fin part 632 protruding from the base part 631, cools the air 60 inside the substantially sealed space, and is disposed in such a direction that the fin part 632 does not interfere with the flow of the air 60. A projection area of the heat sink 63 as viewed from a normal direction (first direction) a includes a region sandwiched by the fin part 632. In the present embodiment, the base part 631 is disposed on an outer circumferential surface of a flow path parallel to the flow direction (first direction) of the first flow channel through which the air 60 flows into the bent portion 611. In addition, the fin part 632, through which the heat sink 63 exchanges heat with the circulating air 60, also extends to a downstream side of a portion where the air 60 flows into the heat sink 63. A Peltier element 64 as a thermoelectric conversion element is disposed such that a heat absorbing surface 641 faces inward and a heat radiation surface 642 faces outward with respect to the cooling duct 61. A radiator 65 diffuses and radiates the heat generated on the heat radiation surface 642 of the Peltier element 64 to the outside of the cooling duct 61. An axial flow fan 66 cools the radiator 65.

Next, a cooling method of the cooling device 6 according to the first embodiment will be described with reference to FIGS. 3, 4, and 5.

The air 60 having received heat from the reflective liquid crystal panel 49 in the color separating and combining optical system 4 flows into the cooling device 6, and flows into the heat sink 63 disposed in the bent portion 611 along the normal direction a. At this time, the air 60 flows into the heat sink 63 through the inflow portion 613 formed on an outer circumferential side (outer circumferential portion) of the bent portion 611. The air 60 is cooled during passing through the heat sink 63, and flows out of the heat sink 63 along the normal direction b. The cooled air 60 is sucked by the sirocco fan 62 and transferred again to the color separating and combining optical system 4 to cool the reflective liquid crystal panel 49.

On the other hand, the heat sink 63 is cooled by a heat absorbing surface 641 of the Peltier element 64 which is attached to the base part 631 so as to be able to transfer heat. Since the heat absorbed by the heat absorbing surface 641 of the Peltier element 64 is transferred to the heat radiation surface 642 by the Peltier effect, the heat radiation surface 642 needs to be cooled. A heat radiation area is expanded by attaching the radiator 65 to the heat radiation surface 642, and further air is blown on the radiator 65 by the axial flow fan 66 to cool the radiator 65 and the heat radiation surface 642 of the Peltier element 64.

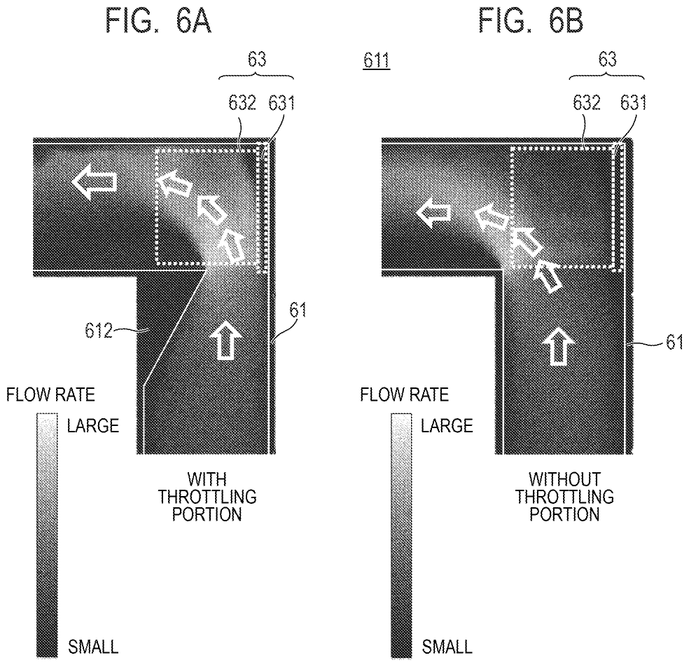

The effect of this embodiment will be described with reference to FIGS. 6A and 6B. In FIGS. 6A and 6B, the flow of the air 60 in the heat sink 63 is compared between a presence and an absence of the throttling portion 612, and a white portion indicates that a flow velocity of the air 60 is high. First, an effect of disposing the heat sink 63 in the bent portion 611 will be described. In the present embodiment, as indicated by an arrow in FIG. 6A, a direction of the flow of the air 60 is changed in the heat sink 63 by disposing the heat sink 63 in the bent portion 611. As a result, a length of passage of the air 60 through the heat sink 63 increases, which has an effect of increasing the heat transfer efficiency between the air 60 and the heat sink 63.

Next, an effect obtained by providing the bent portion 611 with the throttling portion 612 will be described. As shown in FIG. 6A, by providing the throttling portion 612, the air 60 can pass through the outer circumferential side of the bent portion 611. Since the Peltier element 64 is arranged via the outer circumferential surface of the bent portion 611, the temperature of the fin part 632 is lower toward the outer circumferential surface side of the bent portion 611, and thus the air can be cooled more efficiently by allowing the air to flow in from the outer circumferential surface side of the bent portion 611. As a result, since the air 60 flows through the entire heat sink 63 and heat exchange is performed, there is an effect that the heat transfer efficiency between the air 60 and the heat sink 63 is increased as compared with a configuration (shown in FIG. 6B) in which the throttling portion 612 is not provided.

By improving the heat transfer efficiency, the temperature of the air 60 to be blown onto the reflective liquid crystal panel 49 can be efficiently lowered without increasing the size of the heat sink 63, so that the cooling capacity of the cooling device 6 can be enhanced.

By arranging the heat sink 63, the sirocco fan 62, and the reflective liquid crystal panel 49 in this order in the direction in which the air 60 flows, the circulation of the air 60 in the cooling device 6 and the air blowing to the reflective liquid crystal panel 49 can be performed by one sirocco fan 62. Thus, the number of fans in the cooling device 6 can be reduced, and the size and cost of the cooling device 6 can be reduced.

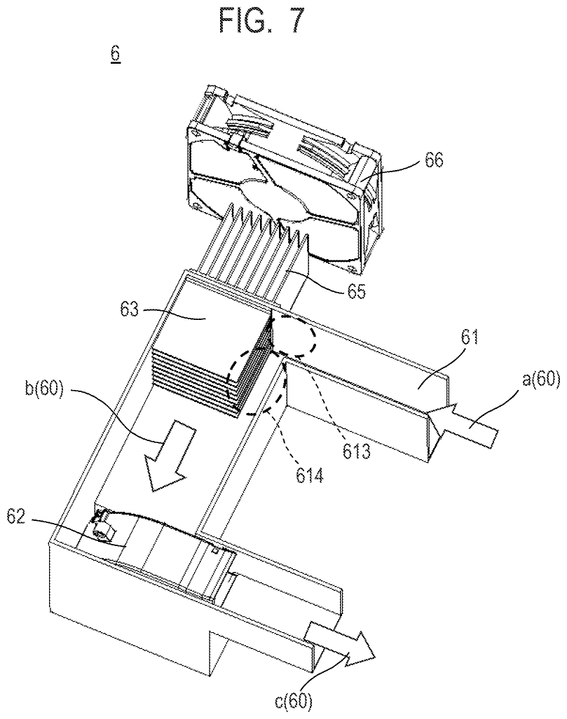

In the cooling device 6 of the present embodiment, the overlap portion 614 is formed by providing the throttling portion 612. However, regardless of the presence or absence of the throttling portion 612, a similar effect can be obtained as long as the heat sink 63 overlaps with the inflow portion 613 as shown in FIG. 7.

Further, although a substantially sealed space is formed together with the color separating and combining optical system 4, a similar effect can be obtained even if the space is not a substantially sealed space.

In this embodiment, the reflective liquid crystal panel 49 in the color separating and combining optical system 4 has been described as a cooling target of the cooling device 6, however the present invention is not limited thereto. The effects of the present invention can be obtained even in a case where the optical element in the projection display apparatus or an optical element of the other optical apparatuses may be a cooling target cooled by the cooling device of the present invention. In the above embodiment, the description has been made on an assumption that the flow path has a positional relationship such that the first direction which is the inflow direction into the bent portion 611, and the second direction which is the outflow direction from the bent portion 611, are substantially perpendicular to each other as shown in the drawings. However, the present invention is not limited to this configuration. The bent portion may be formed at a position such that the first direction which is the inflow direction into the bent portion, and the second direction which is the outflow direction from the bent portion, are in a relationship other than substantially perpendicular to each other. The same applies to a case where the bent portion has an elbow shape.

In the above embodiment, the heat sink 63 includes the base part 631 and the fin part 632 protruding from the base part 631. However, the present invention is not limited to this configuration. The description of the heat sink unit is not limited to the fin of the parallel plate protruding from the base part 631 of the embodiment, and the effect of the present invention can also be enjoyed by a configuration such as a pin or a corrugated plate protruding from the base part 631.

### Embodiment 2

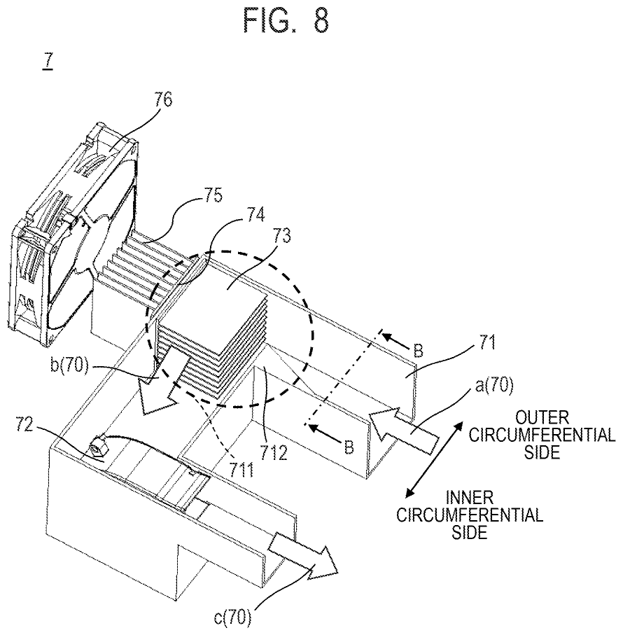

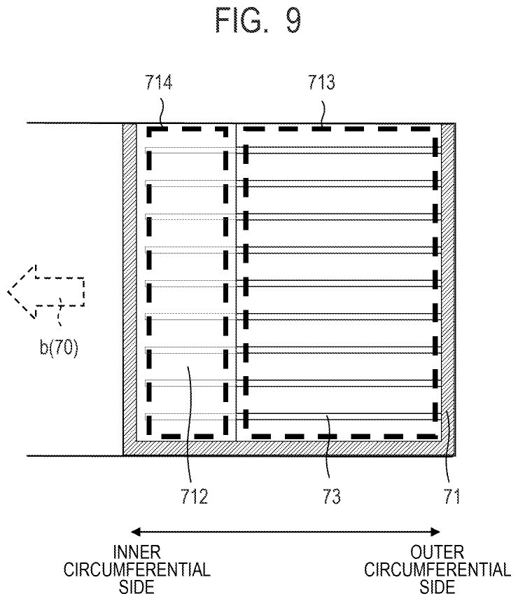

Referring to FIGS. 8, 9, and 10, a configuration of the cooling device 7 according to the second embodiment will be described. FIG. 8 is a configuration diagram of the cooling device 7, and FIG. 9 is a B-B sectional view illustrating a positional relationship between a cooling duct 71 and a heat sink 73 in a bent portion 711, as viewed in a normal direction (first direction) a. The rest of the configuration is the same as that of the first embodiment.

In the second embodiment, the base part 731 of the heat sink 73 in the bent portion 711 is disposed to face the normal direction a. The radiator 75 diffuses and radiates the heat generated on the heat radiation surface of the Peltier element 74 to the outside of the cooling duct 71. The axial flow fan 76 cools the radiator 75. The heat sink 73 includes a projection area (projection area on a projection surface perpendicular to the first direction) larger than the inflow portion 713 as viewed in the normal direction (first direction) a and includes an overlap portion 714 hidden behind the throttling portion 712 as viewed in the normal direction a.

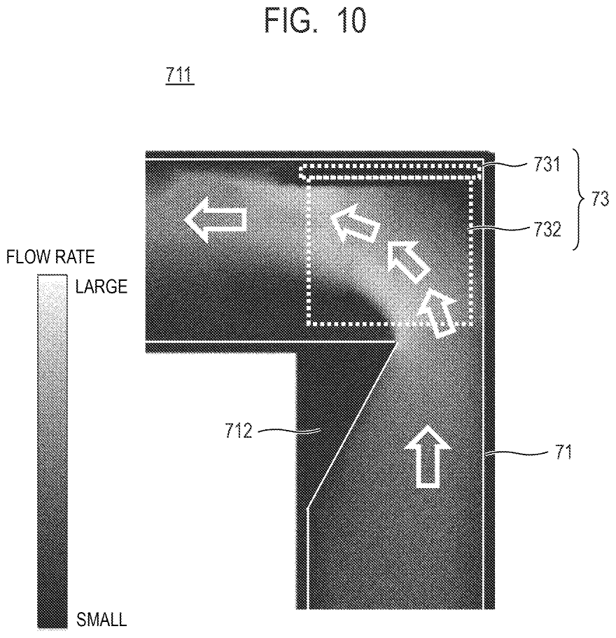

In this configuration FIG. 10 shows a flow of the air 60 in the bent portion 711. The heat sink 73 includes a base part 731 and a fin part 732 protruding from the base part 731, cools the air 70 inside the substantially sealed space, and is disposed in such a direction that the fin part 732 does not interfere with the flow of the air 70. The air 60 flows into the heat sink 73 from the inflow portion 713, collides with the base part 731 to change the direction of the flow, and flows out of the heat sink 73. The air 60 flows into the heat sink 73 as a flow toward the base part 731 that is cooled most, so that a cooling effect of the air 60 with higher heat transfer efficiency can be obtained.

Since the air 60 impinges on the base part 731 at an angle, a temperature boundary layer in the base part 731 can be thinned, and heat transfer efficiency is improved. In this embodiment, since the heat sink 73 has the lowest temperature because the base part 731 is connected to the Peltier element 74, this configuration has an effect of increasing the heat transfer efficiency between the air 60 and the heat sink 73 at a lower temperature portion. Accordingly, since the temperature of the air 60 to be blown to the reflective liquid crystal panel 49 can be efficiently lowered without increasing the size of the heat sink 73, the cooling capacity of the cooling device 7 can be enhanced.

### Embodiment 3

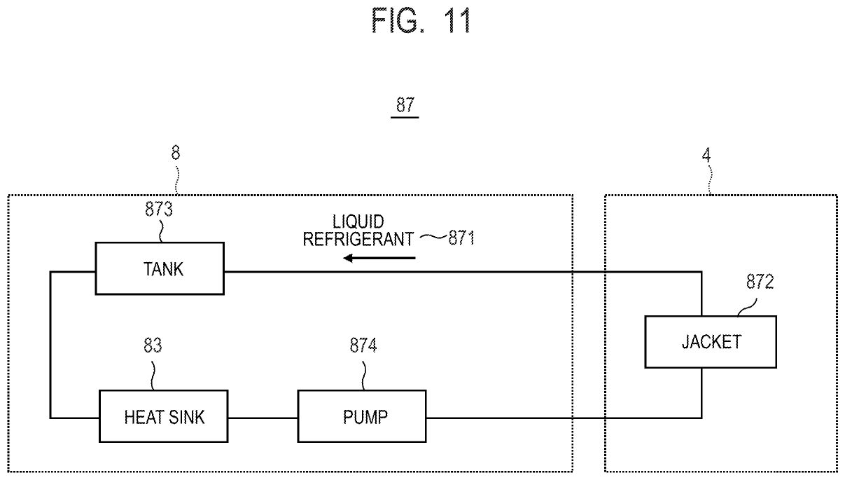

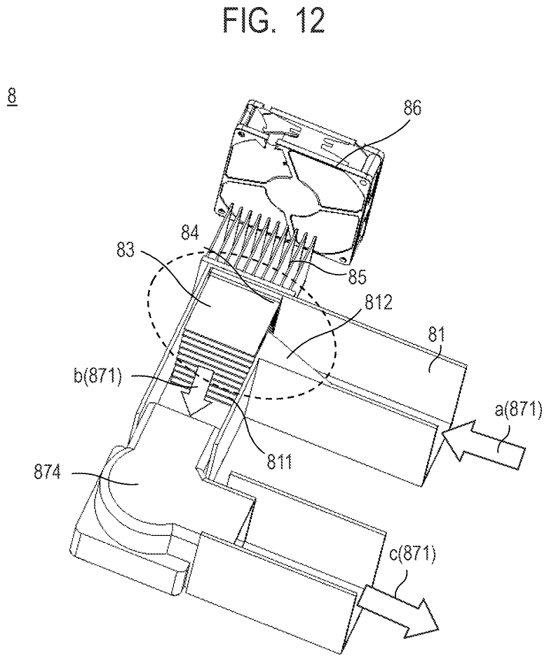

Referring to FIGS. 11 and 12, a configuration of a cooling device 8 according to a third embodiment will be described. The rest of the configuration is the same as that of the first embodiment. The cooling device 8 in the present embodiment uses a liquid cooling system 87 that cools a cooling target by cooling a liquid refrigerant 871 as a cooling medium by a heat sink 83.

FIG. 11 is a schematic diagram of the entire cooling system, and FIG. 12 is a configuration diagram of a portion of the heat sink 83 disposed in the bent portion 811 having the throttling portion 812 in the liquid cooling system 87.

A configuration of a liquid cooling system 87 according to the present embodiment will be described. The liquid cooling system 87 includes a jacket 872, a tank 873, a heat sink 83, and a pump 874 in this order of a flow of a liquid refrigerant 871. The jacket 872 is thermally connected to the reflective liquid crystal panel 49 in the color separating and combining optical system 4 to be cooled. The tank 873 has a liquid refrigerant layer and an air layer. The heat sink 83 cools the liquid refrigerant 871. The pump 874 is a fluid pressure feeding unit having a function of circulating the liquid refrigerant 871.

Next, a cooling method by the liquid cooling system 87 will be described. The liquid refrigerant 871 discharged by the pump 874 is injected into the jacket 872 to cool the reflective liquid crystal panel 49 to be cooled. The liquid refrigerant 871, which has received heat by the jacket 872 and has increased in temperature, passes through the tank 873 and is sent to the heat sink 83 disposed in the bent portion 811. The liquid refrigerant 871 is cooled while passing through the heat sink 83, and then sucked again by the pump 874.

In the present embodiment, by providing the throttling portion 812, the liquid refrigerant 871 can be made to pass through the outer circumferential side of the bent portion 811, and the length of the passage of the liquid refrigerant 871 through the heat sink 83 becomes long, so that there is an effect of increasing the heat transfer efficiency between the liquid refrigerant 871 and the heat sink 83. In this embodiment, since the heat sink 83 is connected to the Peltier element 84 and has the lowest temperature, the heat transfer efficiency between the liquid refrigerant 871 and the heat sink 83 at a lower-temperature portion can be increased.

### Embodiment 4

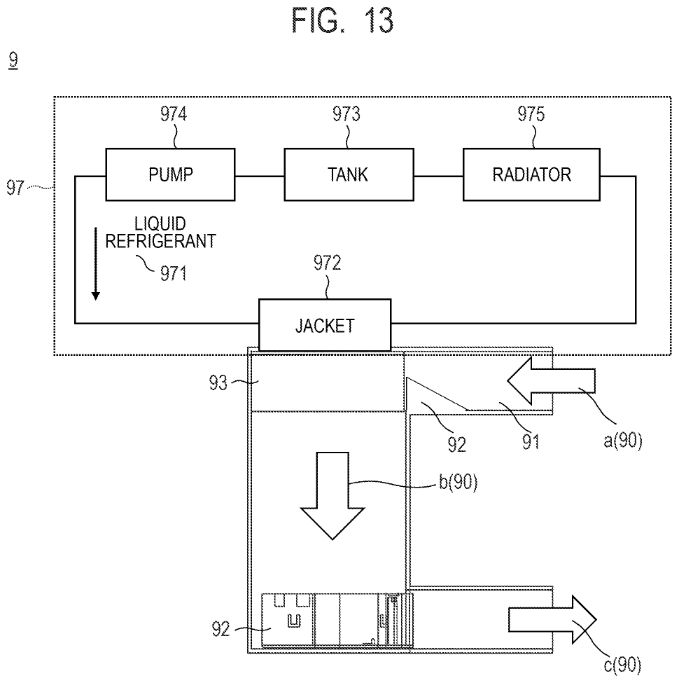

Referring to FIG. 13, a configuration of a cooling device 9 according to the fourth embodiment will be described. Other configurations are the same as those of the first and third embodiments.

In this embodiment, a liquid cooling system 97 is used to cool the heat sink 93. The liquid cooling system 97 includes a jacket 972, a tank 973, a pump 974, and a radiator 975 that are thermally connected to the heat sink 93 as a cooling target.

A cooling method of the liquid cooling system 97 will be described. The liquid refrigerant 971 discharged by the pump 974 is injected into the jacket 972. The jacket 972 transfers the heat received from the heat sink 93 to the liquid refrigerant 971 to cool the heat sink 93. The liquid refrigerant 971 having received heat in the jacket 972 is sent to the radiator 975. In the radiator 975, heat radiating fins are attached to a metal tube, and the liquid refrigerant 971 flowing in the metal tube is cooled by outside air taken in from an outside of the housing of the projection display apparatus by a fan disposed in the projection display apparatus. The liquid refrigerant 971 from which heat is released by the radiator 975 passes through the tank 973 and is sucked again by the pump 974.

In this embodiment, the heat sink 93 can be efficiently cooled by this circulation, and as a result, the temperature of the air 60 in the cooling device 9 is lowered, so that the cooling capacity for the cooling object in the color separating and combining optical system 4 can be enhanced. In the cooling device of the present invention, an optical member has been described as a cooling target, but a heat-generating member such as an electric element, a substrate, or a liquid crystal element may be the cooling target.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-212304, filed Dec. 27, 2021, which is hereby incorporated by reference herein in its entirety.

What is claimed is:

1. A cooling device comprising:
a pressure feeding unit configured to feed a cooling medium for cooling a member;
a flow channel configured to guide the cooling medium to the member, the flow channel including a first flow channel, a second flow channel, a bent portion that connects the first flow channel and the second flow channel; and
a heat sink unit disposed in the bent portion in the flow channel and configured to cool the cooling medium,
wherein an inflow portion of the first flow channel from which the cooling medium flows into the heat sink unit includes an outer circumferential side of the bent portion, and
wherein in a projection onto a projection surface which is a surface perpendicular to a first direction which is a flowing direction of the cooling medium in the first flow channel, a projection area of the heat sink unit is larger than a projection area of the inflow portion.

2. The cooling device according to claim 1,
wherein the heat sink unit comprises a base part and a fin part protruding from the base part, and
wherein in a projection onto the projection surface, the fin part protrudes toward a side of a second direction, which is a direction in which the cooling medium flows in the second flow channel, of a portion from which the cooling medium flows into the heat sink unit in the flow channel.

3. The cooling device according to claim 1, wherein the first flow channel comprises a throttling portion which gradually reduces a cross sectional area of the first flow channel to make the cooling medium flow into the heat sink unit.

4. The cooling device according to claim 1, wherein a projection area on the projection surface of the heat sink unit is larger than a cross sectional area of the first flow channel in a cross section perpendicular to the first direction.

5. The cooling device according to claim 1,
wherein the heat sink unit comprises a base part and a fin part protruding from the base part, and
wherein the base part is disposed in an outer circumferential surface of the flow channel which is parallel to the first direction.

6. The cooling device according to claim 1,
wherein the heat sink unit comprises a base part and a fin part protruding from the base part, and
wherein the base part is disposed in an outer circumferential surface of the flow channel which faces the first direction.

7. The cooling device according to claim 1, wherein the cooling medium circulates in the flow channel.

8. The cooling device according to claim 1, wherein the heat sink unit, the pressure feeding unit and the member are arranged in this order along a direction in which the cooling medium flows in the flow channel by the pressure feeding unit.

9. The cooling device according to claim 1, comprises a thermoelectric conversion element disposed in the heat sink unit so as to be able to transfer heat.

10. The cooling device according to claim 1, wherein the cooling medium comprises an air.

11. The cooling device according to claim 1, wherein the cooling medium comprises a liquid.

12. A projection display apparatus comprises:
a light source;
an illumination optical system configured to generate illumination light from a light emitted from the light source;
a color separating and combining unit that is an optical system configured to generate a projection image from the illumination light;
a projection lens that projects the projection image; and
a cooling device configured to cool at least one of the light source, the illumination optical system, the color separating and combining unit and the projection lens,
wherein the cooling device comprises:
a pressure feeding unit configured to feed a cooling medium for cooling a member;
a flow channel configured to guide the cooling medium to the member, the flow channel including;
a first flow channel, a second flow channel, a bent portion that connects the first flow channel and the second flow channel; and
a heat sink unit disposed in the bent portion in the flow channel and configured to cool the cooling medium,
wherein an inflow portion of the first flow channel from which the cooling medium flows into the heat sink unit includes an outer circumferential side of the bent portion, and
wherein in a projection onto a projection surface which is a surface perpendicular to a first direction which is a flowing direction of the cooling medium in the first flow channel, a projection area of the heat sink unit is larger than a projection area of the inflow portion.

13. An optical apparatus comprising a cooling device, wherein the cooling device comprises:
a pressure feeding unit configured to feed a cooling medium for cooling a member;
a flow channel configured to guide the cooling medium to the member, the flow channel including;
a first flow channel, a second flow channel, a bent portion that connects the first flow channel and the second flow channel; and
a heat sink unit disposed in the bent portion in the flow channel and configured to cool the cooling medium,
wherein an inflow portion of the first flow channel from which the cooling medium flows into the heat sink unit includes an outer circumferential side of the bent portion, and
wherein in a projection onto a projection surface which is a surface perpendicular to a first direction which is a flowing direction of the cooling medium in the first flow channel, a projection area of the heat sink unit is larger than a projection area of the inflow portion.
